(19) United States
(12) Patent Application Publication
(10) Pub. No.: US 2025/0137162 A1
(43) Pub. Date: May 1, 2025

(54) APPARATUS FOR PLATING AND METHOD OF PLATING

(71) Applicant: EBARA CORPORATION, Tokyo (JP)

(72) Inventor: Naoto TAKAHASHI, Tokyo (JP)

(21) Appl. No.: 18/026,810

(22) PCT Filed: Mar. 31, 2022
(86) PCT No.: PCT/JP2022/016809

§ 371 Date: Jan. 13, 2025

(51) Int. Cl. C25D 21/04; C25D 17/00

(52) U.S. Cl. CPC C25D 21/04; C25D 17/001

(57) ABSTRACT

There is provided an apparatus for plating, comprising: a plating tank configured to store a plating solution therein; an anode placed in the plating tank and provided with a plurality of through holes; a substrate holder provided to hold a substrate to be opposed to the anode; a barrier membrane placed to be brought into close contact with a first face on a substrate side of the anode; and a rear face plate placed to be opposed to a second face of the anode that is on an opposite side to the first face and to be separated from the second face by a predetermined distance and configured to regulate an amount of bubbles generated from the anode and accumulated on the second face.

### TECHNICAL FIELD

The present disclosure relates to an apparatus for plating and a method of plating.

### BACKGROUND ART

A plating apparatus as described in US Patent Application Publication No. 2020-0017989 (PTL 1) has been known as a plating apparatus configured to perform plating of a substrate such as a semiconductor wafer. The plating apparatus includes a plating tank configured to store a plating solution therein and provided with an anode placed therein; a substrate holder configured to hold a substrate as a cathode such as to be opposed to the anode; and a barrier membrane placed between the anode and the substrate holder to part inside of the plating tank into an anode chamber and a cathode chamber. The plating apparatus of this configuration causes the plating solution to flow along a surface of the substrate. The barrier membrane is placed below a frame fixed in the plating tank. When a pressure in the cathode chamber becomes higher than a pressure in the anode chamber, the barrier membrane is separated from the frame to be extended downward and is likely to form a pocket for trapping bubbles between the frame and the barrier membrane. In order to prevent such a phenomenon, the apparatus described in Description of US Patent Application No. 2020-0017989 (PTL 1) is configured to regulate the supply of the plating solution into the anode chamber such that the pressure in the anode chamber becomes or is kept higher than the pressure in the cathode chamber and thereby prevents the barrier membrane from being extended downward.

### CITATION LIST

### Patent Literatures

PTL1: US Patent Application Publication No. 2020-0017989

### SUMMARY OF INVENTION

### Technical Problem

In the plating apparatus, bubbles of a gas such as oxygen generated at the anode may be unevenly accumulated on the substrate, the barrier membrane and the like. This is likely to increase the ion conduction resistance (electric resistance) in a location where bubbles are accumulated and to deteriorate the uniformity in a distribution of the thickness of a plating film. For example, bubbles may be accumulated on a plating surface or a surface to be plated of the substrate and destabilize production of a plating film on the substrate. Furthermore, bubbles may be accumulated on the barrier membrane to work as a resistive component and destabilize plating. In a configuration that a resistor plate of a porous structure is placed in the vicinity of the substrate, bubbles may be accumulated on the resistor plate to work as a resistive component and destabilize plating.

There is also a possibility that the gas (for example, active oxygen) generated at the anode reacts with an additive in the plating solution to deteriorate the additive.

Description of US Patent Application No. 2020-0017989 (PTL 1) does not mention the effects of the gas generated at the anode on plating.

By taking into account the foregoing, one object of the present disclosure is to suppress effects of bubbles generated at an anode, on uniformity in a distribution of a thickness of a plating film in an apparatus for plating.

### Solution to Problem

According to one aspect, there is provided an apparatus for plating, comprising: a plating tank configured to store a plating solution therein; an anode placed in the plating tank and provided with a plurality of through holes; a substrate holder provided to hold a substrate to be opposed to the anode; a barrier membrane placed to be brought into close contact with a first face on a substrate side of the anode; and a rear face plate placed to be opposed to a second face of the anode that is on an opposite side to the first face and to be separated from the second face by a predetermined distance and configured to regulate an amount of bubbles generated from the anode and accumulated on the second face.

### BRIEF DESCRIPTION OF DRAWINGS

FIG. 1 is a perspective view illustrating the overall configuration of a plating apparatus according to one embodiment;

FIG. 2 is a plan view illustrating the overall configuration of the plating apparatus according to the embodiment;

FIG. 3 is a sectional view illustrating the configuration of a plating module according to one embodiment;

FIG. 4 is a schematic diagram illustrating an anode chamber of the plating module viewed from the bottom;

FIG. 5 is an enlarged sectional view illustrating the vicinity of an anode;

FIG. 6 is a sectional view illustrating a fixation structure of a barrier membrane to the anode;

FIG. 7 is a sectional view illustrating another fixation structure of the barrier membrane to the anode;

FIG. 8 is a sectional view illustrating the configuration of a plating module according to a second embodiment;

FIG. 9 is a photograph showing a plating module for experiment (without a barrier membrane);

FIG. 10 is a photograph showing a plating module for experiment (with a barrier membrane);

FIG. 11A is a photograph illustrating a procedure of assembling a plating module for experiment (with a barrier membrane);

FIG. 11B is a photograph illustrating the procedure of assembling the plating module for experiment (with the barrier membrane);

FIG. 11C is a photograph illustrating the procedure of assembling the plating module for experiment (with the barrier membrane);

FIG. 11D is a photograph illustrating the procedure of assembling the plating module for experiment (with the barrier membrane);

FIG. 11E is a photograph illustrating the procedure of assembling the plating module for experiment (with the barrier membrane);

FIG. 12 is a schematic sectional view illustrating the plating module for experiment (with the barrier membrane);

FIG. 13 is a graph showing results of measurement of an anode voltage in the process of plating;

FIG. 14A is a photograph showing a plating module (without a barrier membrane) prior to plating;

FIG. 14B is a photograph showing the plating module (without the barrier membrane) in the course of plating;

FIG. 15A is a photograph showing a plating module (with a barrier membrane) prior to plating;

FIG. 15B is a photograph showing the plating module (with the barrier membrane) in the course of plating;

FIG. 16A is a schematic diagram illustrating movement of bubbles generated from an anode;

FIG. 16B is a schematic diagram illustrating movement of bubbles generated from the anode;

FIG. 17A is a sectional view illustrating the structure in the vicinity of an anode in a plating module according to a third embodiment;

FIG. 17B is a sectional view illustrating the structure in the vicinity of the anode in the plating module according to the third embodiment;

FIG. 18 is a bottom view illustrating the structure in the vicinity of the anode in the plating module according to the third embodiment, viewed from the bottom;

FIG. 19 is a plan view and a sectional view illustrating a bubble regulating plate according to the third embodiment;

FIG. 20 is schematic diagrams illustrating discharge of bubbles on a rear face of the anode;

FIG. 21A is a sectional view illustrating the structure in the vicinity of an anode in a plating module according to a fourth embodiment;

FIG. 21B is a sectional view illustrating the structure in the vicinity of the anode in the plating module according to the fourth embodiment;

FIG. 22 is a bottom view illustrating the structure in the vicinity of the anode in the plating module according to the fourth embodiment, viewed from the bottom;

FIG. 23 is schematic diagrams illustrating discharge of bubbles on a rear face of the anode;

FIG. 24 is a sectional view illustrating the structure in the vicinity of an anode in a plating module according to a modification;

FIG. 25 is a bottom view illustrating the structure in the vicinity of the anode in the plating module according to the modification, viewed from the bottom; and

FIG. 26 is a plan view and a sectional view illustrating a bubble regulating plate according to the modification.

### DESCRIPTION OF EMBODIMENTS

The following describes a plating apparatus 1000 according to one embodiment of the present disclosure with reference to drawings. The drawings are schematically illustrated, in order to facilitate understanding the features of substances. The ratio of dimensions of respective components and the like in the drawings may not be equal to those in the actual state. Cartesian coordinates X-Y-Z are illustrated in some of the drawings for the purpose of reference. In the Cartesian coordinates, a Z direction corresponds to an upward direction, and a −Z direction corresponds to a downward direction (direction where the gravity acts).

### First Embodiment

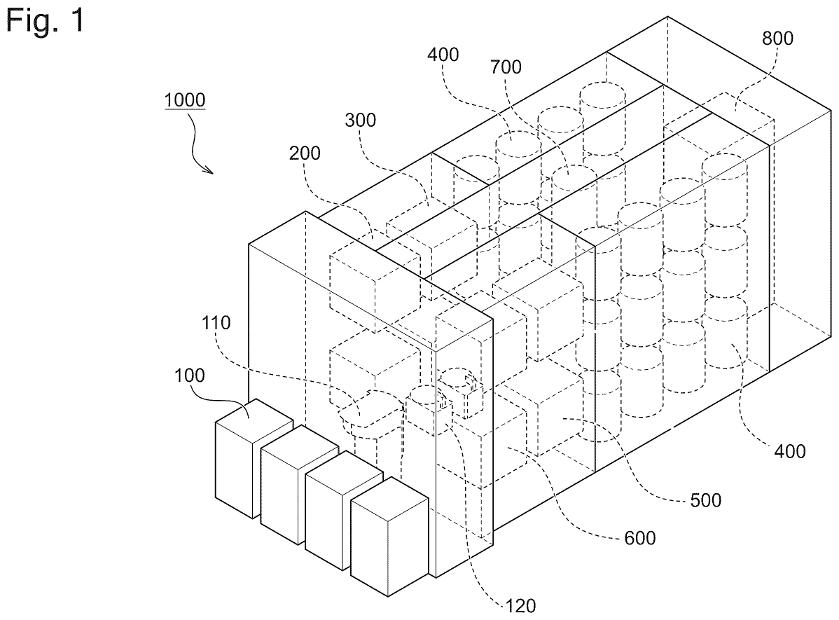

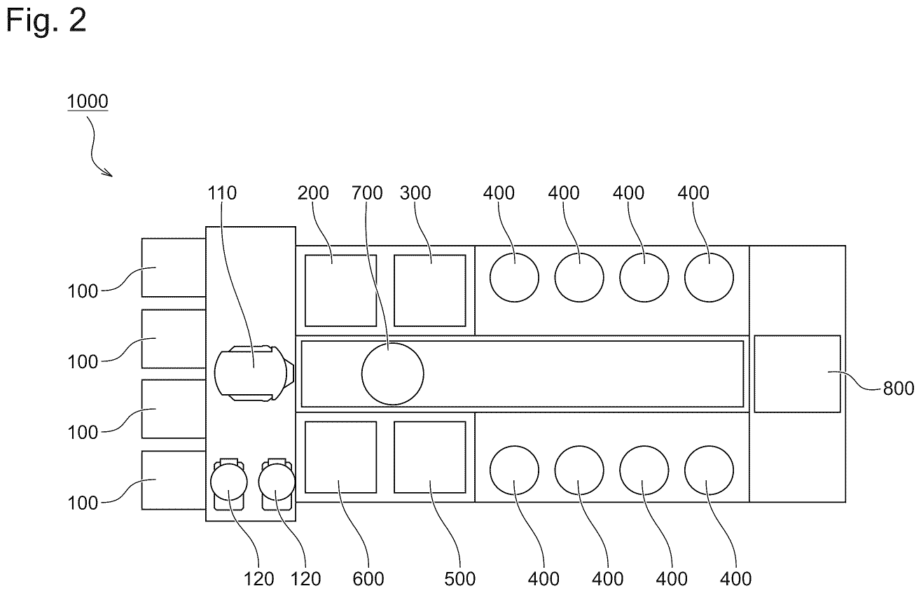

FIG. 1 is a perspective view illustrating the overall configuration of the plating apparatus of this embodiment. FIG. 2 is a plan view illustrating the overall configuration of the plating apparatus of this embodiment. As illustrated in FIGS. 1 and 2, a plating apparatus 1000 includes load ports 100, a transfer robot 110, aligners 120, pre-wet modules 200, pre-soak modules 300, plating modules 400, cleaning modules 500, spin rinse dryers 600, a transfer device 700, and a control module 800.

The load port 100 is a module for loading a substrate housed in a cassette, such as a FOUP, (not illustrated) to the plating apparatus 1000 and unloading the substrate from the plating apparatus 1000 to the cassette. While the four load ports 100 are arranged in the horizontal direction in this embodiment, the number of load ports 100 and arrangement of the load ports 100 are arbitrary. The transfer robot 110 is a robot for transferring the substrate that is configured to grip or release the substrate between the load port 100, the aligner 120, the pre-wet module 200, and the spin rinse dryers 600. The transfer robot 110 and the transfer device 700 can perform delivery and receipt of the substrate via a temporary placement table (not illustrated) to grip or release the substrate between the transfer robot 110 and the transfer device 700.

The aligner 120 is a module for adjusting a position of an orientation flat, a notch, and the like of the substrate in a predetermined direction. While the two aligners 120 are disposed to be arranged in the horizontal direction in this embodiment, the number of aligners 120 and arrangement of the aligners 120 are arbitrary. The pre-wet module 200 wets a surface to be plated of the substrate before a plating process with a process liquid, such as pure water or deaerated water, to replace air inside a pattern formed on the surface of the substrate with the process liquid. The pre-wet module 200 is configured to perform a pre-wet process to facilitate supplying the plating solution to the inside of the pattern by replacing the process liquid inside the pattern with a plating solution during plating. While the two pre-wet modules 200 are disposed to be arranged in the vertical direction in this embodiment, the number of pre-wet modules 200 and arrangement of the pre-wet modules 200 are arbitrary.

For example, the pre-soak module 300 is configured to remove an oxidized film having a large electrical resistance present on, a surface of a seed layer formed on the surface to be plated of the substrate before the plating process by etching with a process liquid, such as sulfuric acid and hydrochloric acid, and perform a pre-soak process that cleans or activates a surface of a plating base layer. While the two pre-soak modules 300 are disposed to be arranged in the vertical direction in this embodiment, the number of pre-soak modules 300 and arrangement of the pre-soak modules 300 are arbitrary. The plating module 400 performs the plating process on the substrate. There are two sets of the 12 plating modules 400 arranged by three in the vertical direction and by four in the horizontal direction, and the total 24 plating modules 400 are disposed in this embodiment, but the number of plating modules 400 and arrangement of the plating modules 400 are arbitrary.

The cleaning module 500 is configured to perform a cleaning process on the substrate to remove the plating solution or the like left on the substrate after the plating process. While the two cleaning modules 500 are disposed to be arranged in the vertical direction in this embodiment, the number of cleaning modules 500 and arrangement of the cleaning modules 500 are arbitrary. The spin rinse dryer 600 is a module for rotating the substrate after the cleaning process at high speed and drying the substrate. While the two spin rinse dryers are disposed to be arranged in the vertical direction in this embodiment, the number of spin rinse dryers and arrangement of the spin rinse dryers are arbitrary. The transfer device 700 is a device for transfer the substrate between the plurality of modules inside the plating apparatus 1000. The control module 800 is configured to control the plurality of modules in the plating apparatus 1000 and can be configured of, for example, a general computer including input/output interfaces with an operator or a dedicated computer.

An example of a sequence of the plating processes by the plating apparatus 1000 will be described. First, the substrate housed in the cassette is loaded on the load port 100. Subsequently, the transfer robot 110 grips the substrate from the cassette at the load port 100 and transfers the substrate to the aligners 120. The aligner 120 adjusts the position of the orientation flat, the notch, or the like of the substrate in the predetermined direction. The transfer robot 110 grips or releases the substrate whose direction is adjusted with the aligners 120 to the pre-wet module 200.

The pre-wet module 200 performs the pre-wet process on the substrate. The transfer device 700 transfers the substrate on which the pre-wet process has been performed to the pre-soak module 300. The pre-soak module 300 performs the pre-soak process on the substrate. The transfer device 700 transfers the substrate on which the pre-soak process has been performed to the plating module 400. The plating module 400 performs the plating process on the substrate.

The transfer device 700 transfers the substrate on which the plating process has been performed to the cleaning module 500. The cleaning module 500 performs the cleaning process on the substrate. The transfer device 700 transfers the substrate on which the cleaning process has been performed to the spin rinse dryer 600. The spin rinse dryer 600 performs the drying process on the substrate. The transfer robot 110 receives the substrate from the spin rinse dryer 600 and transfers the substrate, on which the drying process is performed, to the cassette at the load port 100. Finally, the cassette housing the substrate is unloaded from the load port 100.

The configuration of the plating apparatus 1000 illustrated in FIG. 1 and FIG. 2 is only one example, and the configuration of the plating apparatus 1000 is not limited to the configuration of FIG. 1 and FIG. 2.

### [Plating Module]

The following describes the plating module 400. The plurality of plating modules 400 included in the plating apparatus 1000 of the embodiment have similar configurations. Accordingly the description regards one plating module 400.

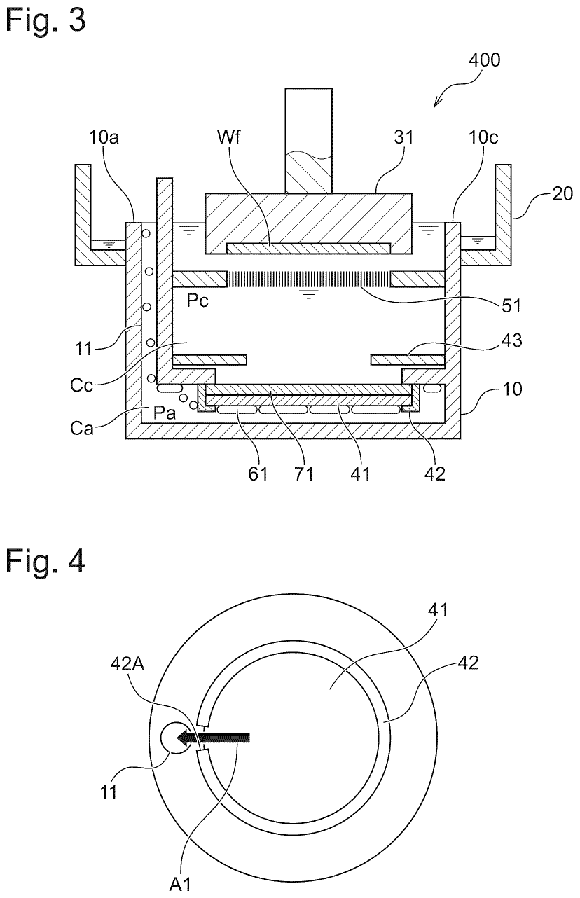

FIG. 3 is a sectional view illustrating the configuration of the plating module according to one embodiment. FIG. 4 is a schematic diagram illustrating an anode chamber of the plating module viewed from the bottom.

The plating apparatus 1000 according to the embodiment is a face down-type or a cup-type plating apparatus that causes a plating surface or a surface to be plated of a substrate to face down and to come into contact with a plating solution. The plating module 400 in the plating apparatus 1000 of the embodiment mainly includes a plating tank 10, an anode 41 placed in the plating tank 10, and a substrate holder 31 configured to hold a substrate Wf that serves as a cathode and that is arranged be opposed to the anode 41. The plating module 400 may be provided with a rotating mechanism, a tilting mechanism and a lift mechanism (not shown) configured to rotate, tilt and lift up and down the substrate holder 31. An overflow tank 20 may be provided on an outer side of the plating tank 10.

The plating tank 10 is configured by a bottomed vessel having an opening on an upper side thereof. The plating tank 10 has a bottom wall and a side wall extended upward from an outer periphery of this bottom wall and is open on an upper portion of this side wall. The plating tank 10 has an internal space in a cylindrical shape to store a plating solution therein. The plating solution may be any solution including an ion of a metal element to form a plating film, and its concrete examples are not specifically limited. According to the embodiment, a copper plating process is employed as one example of a plating process, and a copper sulfate solution is used as one example of the plating solution. According to the embodiment, the plating solution includes a predetermined additive. The plating solution is, however, not limited to this composition but may be prepared not to include any additive. Inside of the plating tank 10 is parted into an anode chamber Ca and a cathode chamber Cc by a barrier membrane 71. A plating solution Pa in the anode chamber Ca and a plating solution Pc in the cathode chamber Cc may be identical with each other or may be different from each other. For example, the plating solution Pa in the anode chamber Ca and the plating solution Pc in the cathode chamber Cc may include or not include an additive and may have an identical concentration of the additive or have different concentrations of the additive.

The overflow tank 20 is configured by a bottomed vessel that is placed outside of the plating tank 10. The overflow tank 20 temporarily stores the plating solution that overflows from an upper edge of the plating tank 10. In one example, the plating solution in the overflow tank 20 is discharged from an outlet (not shown) for the overflow tank 20, is temporarily accumulated in a reservoir tank (not shown) and is returned to the plating tank 10. In the illustrated example of FIG. 3, an overflow weir 10c that allows the plating solution to overflow from the cathode chamber Cc into the overflow tank 20 and an overflow weir 10a that allows the plating solution to overflow from the anode chamber Ca into the overflow tank 20 are set at approximately identical heights.

The anode 41 is placed in a lower portion inside of the plating tank 10. The concrete type of the anode 41 is not specifically limited, but a soluble anode or an insoluble anode may be used. According to the embodiment, an insoluble anode is used as the anode 41. The concrete type of this insoluble anode is not specifically limited, but platinum, titanium, iridium oxide and the like (for example, IrO2/Ti or Pt/Ti) may be used. A top coat layer may be provided on a surface of the anode 41 with a view to, for example, suppressing degradation of the additive included in the plating solution.

According to the embodiment, an anode mask 43 is provided on an upper face side (substrate Wf-side) of the anode 41. The anode mask 43 has an opening which the anode 41 is exposed from and serves as an electric field regulating member configured to adjust an exposure range of the anode 41 by the opening and thereby regulate an electric field from the anode 41 toward the substrate Wf. The anode mask 43 may be an anode mask having predetermined opening dimensions or may be a variable anode mask having variable opening dimensions. For example, the anode mask 43 may have a plurality of blades to adjust the opening dimensions of the opening by a mechanism similar to an aperture or a diaphragm of a camera.

A porous resistor 51 is placed above the barrier membrane 71 inside of the plating tank 10. More specifically, the resistor 51 is configured by a porous plate member having a plurality of pores (fine pores). The plating solution on a lower side of the resistor 51 is allowed to pass through the resistor 51 and flow to an upper side of the resistor 51. This resistor 51 is a member provided to homogenize an electric field formed between the anode 41 and the substrate Wf. Placing such a resistor 51 in the plating tank 10 facilitates uniformization of the film thickness of a plating film (plating layer) formed on the substrate Wf. The resistor 51 is, however, not an essential component according to the embodiment, but the embodiment may be configured without the resistor 51.

A paddle (not shown) may be placed in the vicinity of the substrate Wf (between the resistor 51 and the substrate Wf according to the embodiment) inside of the plating tank 10. The paddle moves back and forth in a direction approximately parallel to a surface to be plated or a plating surface of the substrate Wf to generate a strong flow of the plating solution on the surface of the substrate Wf. This homogenizes the ion in the plating solution in the vicinity of the surface of the substrate Wf and improves the in-plane uniformity of the plating film formed on the surface of the substrate Wf.

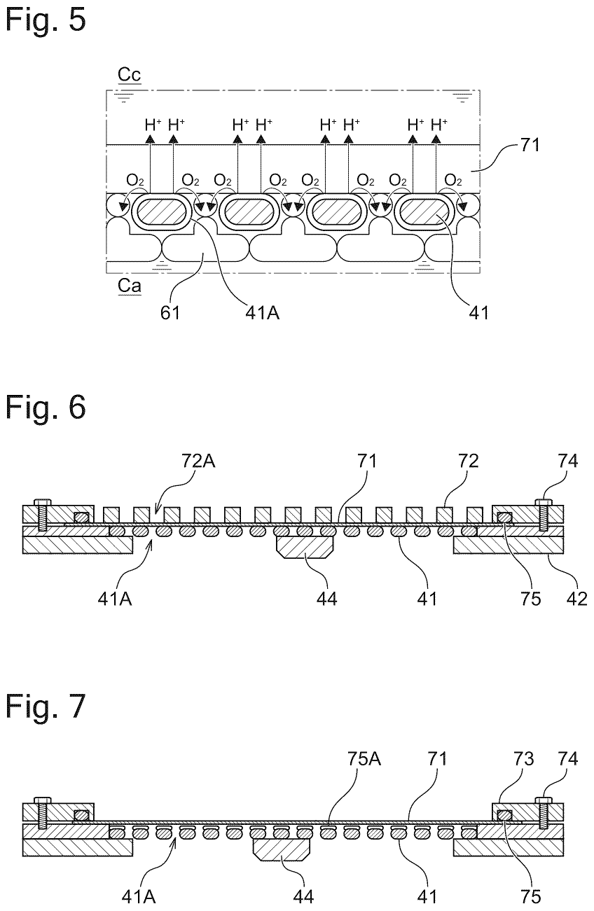

According to the embodiment, as shown in FIG. 5 to FIG. 7, the anode 41 is a plate-like member having a large number of through holes 41A. The anode 41 may be a plate-like member having a lath (wire net) structure or another structure provided with a large number of through holes. The thickness of the anode 41 is not specifically limited but is preferably about 0.5 mm to 3 mm in terms of the intensity of the anode 41 itself and the easiness of discharge of oxygen that is generated on the surface of the anode 41, through the through holes to a rear face of the anode 41. The shape and the size of the through holes are not specifically limited, but the opening size (the diameter in the case of circular through holes or the length of one side in the case of rectangular through holes) is preferably about 1 mm to 5 mm in terms of the easiness of processing and the stability of a voltage in a plating process. The anode 41 is supported by an anode holder 42 that is also called an anode retainer in the plating tank 10. The barrier membrane 71 (for example, a Nafion (registered trademark) membrane or a porous membrane) having ion permeability to be impregnated with and moistened with the plating solution, is joined with or is brought into close contact with a front face of the anode 41 (a cathode/substrate-side face, an upper face in the illustrated example). According to the embodiment, the inside of the plating tank 10 is parted into the anode chamber Ca and the cathode chamber Cc by this barrier membrane 71. The barrier membrane 71 is a membrane that allows a cation (for example, hydrogen ion H+) included in the plating solution to permeate through but does not allow bubbles of a gas (for example, oxygen gas) and the additive included in the plating solution to permeate through. In the case of using an insoluble anode, the hydrogen ion H+ is generated in the plating solution on the surface of the anode. The barrier membrane 71 may be, for example, a neutral membrane, an ion exchange membrane or a combination thereof. The barrier membrane 71 may be comprised of a plurality of membranes or layers laid one upon another. The configuration of the barrier membrane 71 is only one example, and the barrier membrane 71 may have another configuration.

FIG. 5 is an enlarged sectional view illustrating the vicinity of the anode 41. The anode 41 has a large number of through holes 41A, so that the surface of the anode 41 is kept constantly moistened with the plating solution that is supplied through the through holes 41A even during an electrode reaction. The barrier membrane 71 is the membrane having ion permeability to be impregnated with and moistened with the plating solution. As shown in this drawing, the plating solution reacts with the anode 41 on a substrate-side face thereof (a location which the barrier membrane 71 is brought into close contact with/adheres to or its neighborhood), and the cation (for example, hydrogen ion H+) is transmitted through the barrier membrane 71 to the cathode chamber Cc, i.e., to a substrate side. Accordingly, an ion conductive path (current path) is formed from the substrate-side face (the location which the barrier membrane 71 is brought into close contact with/adheres to or its neighborhood) of the anode 41 through inside of the barrier membrane 71 to the substrate Wf. Bubbles 61 of a gas (for example, oxygen O2) generated on the surface of the anode 41, on the other hand, are not allowed to pass through the barrier membrane 71 but move through the large number of through holes 41A of the anode 41 to a rear face (a face opposite to the front face) side of the anode 41. The bubbles 61 moved to the rear face side of the anode 41 are discharged through a discharge outlet 11 provided outside of the barrier membrane 71 (shown in FIG. 3 and FIG. 4) to outside of the plating tank 10.

This configuration that the barrier membrane 71 is brought into close contact with/adheres to the substrate-side face of the anode 41 suppresses the bubbles 61 generated on the surface of the anode 41 from being diffused to the substrate Wf-side. This accordingly suppresses the bubbles 61 from being diffused to the substrate side and adhering to the resistor 51, the substrate Wf and the like. Furthermore, the configuration that the barrier membrane 71 is brought into close contact with/adheres to the anode 41 prevents accumulation of the bubbles 61 between the barrier membrane 71 and the anode 41. More specifically, this configuration avoids a problem that the bubbles 61 are accumulated on a rear face of the barrier membrane 71 as in the case where the barrier membrane 71 is separated from the anode 41. The rear face side of the anode 41 that forms a discharge pathway of the bubbles 61 is not a primary ion conductive path between the anode 41 and the substrate Wf. The bubbles 61, if present, on the rear face side of the anode 41 accordingly do not work as an ion conduction resistive component between the anode and the substrate and hardly affect the ion conduction (plating current) between the anode and the substrate.

This configuration enables the cation (H+) to be conducted from the substrate-side face (the location which the barrier membrane 71 is brought into close contact with/adheres to or its neighborhood) of the anode 41 through the barrier membrane 71 to the substrate Wf-side. Accordingly, this certainly provides an ion conductive path between the anode 41 and the substrate Wf, while avoiding the effects of the bubbles 61.

As described above, this configuration provides the stable ion conductive path between the anode and the cathode and prevents the bubbles 61 from being accumulated on the ion conductive path between the anode and the cathode and adversely affecting the ion conduction. As a result, this reduces the effects of the bubbles generated on the anode and allows for stable plating on the substrate, thus enhancing the uniformity in the thickness of the plating film.

According to the embodiment, in the plating tank 10, the discharge outlet 11 of the gas is provided outside of the barrier membrane 71 (as shown in FIG. 3 and FIG. 4). The bubbles 61 moving to the rear face side of the anode 41 are discharged through the discharge outlet 11 to outside of the plating tank 10 as shown in FIG. 3. This configuration enables the bubbles 61 generated on the anode 41 to be naturally discharged via the discharge outlet 11 and does not need to discharge the bubbles by circulation of the plating solution in the anode chamber Ca. The plating solution in the anode chamber Ca may, however, be circulated. This configuration further accelerates discharge of the bubbles present in the anode chamber Ca. This configuration suppresses oxygen from being excessively and non-uniformly accumulated below the anode 41 and accordingly accelerates discharge of the bubbles (the oxygen gas) present in the through holes 41A of the anode 41 to further enhance the uniformity of the plating film. The circulation of the plating solution in the anode chamber Ca may be configured similarly to a circulation path 80 of the plating solution in the cathode chamber Cc. This circulation, however, causes the plating solution discharged from the anode chamber Ca to be returned to the anode chamber Ca.

According to the embodiment, as shown in FIG. 4, a cut 42A is provided in a lower face of the anode holder 42. The cut 42A may be formed such that the height of the anode holder 42 is reduced at the position of the cut 42A or such that the anode holder 42 is made discontinuous at the position of the cut 42A. This enables the bubbles 61 accumulated on the rear face of the anode 41 to readily move through the cut 42A toward the discharge outlet 11 in the case where a lower portion of the anode holder 42 is protruded to be lower than the rear face of the anode 41 as shown in FIG. 6 and FIG. 7. It is preferable that the cut 42A is provided near the discharge outlet 11 or at a position opposed to the discharge outlet 11. It is, however, not essential to provide the cut 42A in the anode holder 42. A plurality of the cuts 42A and a plurality of the discharge outlets 11 may be formed in the circumference of the anode 41. The anode 41 itself may be inclined diagonally to the horizontal, with a view to facilitating discharge of the bubbles 61. In this configuration, it is preferable to place the cut 42A above the center of the anode.

FIG. 6 and FIG. 7 are sectional views illustrating fixation structures of the barrier membrane 71 to the anode 41. In these drawings, a boss for power feeding 44 is provided in a center area on the rear face of the anode 41 to feed electricity to the anode 41. The boss for power feeding 44 may be formed integrally with the anode 41 or may be attached to the anode 41. A retainer plate 72 (shown in FIG. 6) and a retainer ring 73 (shown in FIG. 7) are omitted from the illustration of FIG. 3.

In the illustrated example of FIG. 6, the barrier membrane 71 is pressed against the substrate side-face of the anode 41 by a retainer plate 72 having a large number of through holes 72A to be fixed in such a state that the barrier membrane 71 is brought into close contact with/adheres to the upper face of the anode 41. The retainer plate 72 is fixed to the anode holder 42 by means of fastening members 74, for example, screws, such as to press down the anode 41 and the barrier membrane 71. This configuration places the barrier membrane 71 between the retainer plate 72 and the anode 41 and causes the barrier membrane 71 to be brought into close contact with/adhere to the anode 41. Furthermore, a seal member 75 (for example, an O-ring) is provided between the retainer plate 72 and the barrier membrane 71 to seal between the retainer plate 72 and the barrier membrane 71. It is preferable that the anode holder 42 and the retainer plate 72 are made of a material that is not corroded by the plating solution, for example, a resin such as vinyl chloride or a metal such as Pt or Ti.

In the illustrated example of FIG. 7, the barrier membrane 71 is joined with and fixed to the substrate side-face of the anode 41. A joint layer/adhesive layer 75A serving to join the barrier membrane 71 with the anode 41 preferably has ion permeability. The joint layer 75A is, for example, a resin joint layer having an ion exchange group or a porous joint layer including a resin and a filler and may be made of a perfluorocarbon material having a sulfonic acid group as an example. An outer peripheral portion of the barrier membrane 71 is pressed against and fixed to the anode holder 42 by a retainer ring 73. Furthermore, a seal member 75 (for example, an O-ring) is provided between the retainer ring 73 and the barrier membrane 71 to seal between the retainer ring 73 and the barrier membrane 71. It is preferable that the anode holder 42 and the retainer ring 73 are made of a material that is not corroded by the plating solution, for example, a resin such as vinyl chloride or a metal such as Pt or Ti.

### Second Embodiment

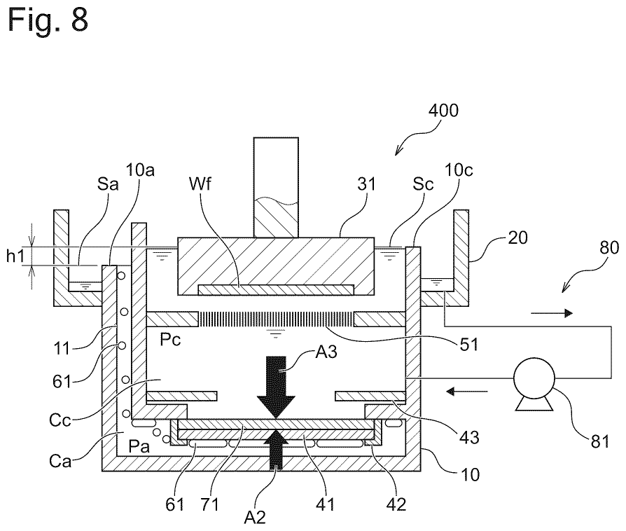

FIG. 8 is a sectional view illustrating the configuration of a plating module according to a second embodiment. The following mainly describes a configuration different from that of the above embodiment with omitting the description on the configuration similar to that of the above embodiment. A plating module of this embodiment is configured such that a lowermost portion of a side wall of a cathode chamber Cc in a plating tank 10 is slightly higher than a lowermost portion of a side wall of a discharge outlet 11. An overflow surface Sc in the cathode chamber Cc of the plating tank 10 is accordingly set to be slightly (i.e., in such a degree that minimizes a liquid movement via a barrier membrane) higher than an overflow surface Sa in an anode chamber Ca (the discharge outlet 11). The discharge outlet 11 is connected with the anode chamber Ca, so that the overflow surface Sa of the discharge outlet 11 is the overflow surface of the anode chamber Ca. In this drawing, hl denotes a difference between the overflow surface Sc and the overflow surface Sa. In this configuration, slightly applying a pressure to the cathode chamber Cc against the anode chamber Ca as shown by arrows A3 and A2 in this drawing enhances the contact/adhesion of a barrier membrane 71 to an anode 41.

The plating tank 10 has an overflow weir 10c that allows the plating solution to overflow from the cathode chamber Cc to outside of the plating tank 10. In this illustrated example, the overflow weir 10c is a side wall of the cathode chamber Cc between the cathode chamber Cc of the plating tank 10 and an overflow tank 20. The plating tank 10 also has an overflow weir 10a that allows the plating solution to overflow from the anode chamber Ca to outside of the plating tank 10. In this illustrated example, the overflow weir 10a is a side all between the discharge outlet 11 of the plating tank 10 and the overflow tank 20 (i.e., a side wall of part of the discharge outlet 11 of the plating tank 10). Setting the height of the overflow weir 10c (the overflow surface Sc) higher than the height of the overflow weir 10a (the overflow surface Sa) causes a pressure difference between the cathode chamber Cc and the anode chamber Ca (the pressure in the cathode chamber Cc>the pressure in the anode chamber Ca). The pressure difference between the cathode chamber Cc and the anode chamber Ca is set, i.e., the heights of the respective overflow weirs 10c and 10a, are set in such a degree that minimizes liquid movement via the barrier membrane 71 (or in such a degree that does not cause excessive liquid movement). The other configuration is similar to that of the above embodiment, so that the description thereof is omitted.

In the embodiment described above and in this embodiment, a circulation path 80 may be provided to circulate the plating solution collected in the overflow tank 20 to the cathode chamber Cc by a pump 81, as shown in FIG. 8. One or a plurality of reservoirs may be provided in the middle of the circulation path 80.

### [Experimental Examples of Plating Module]

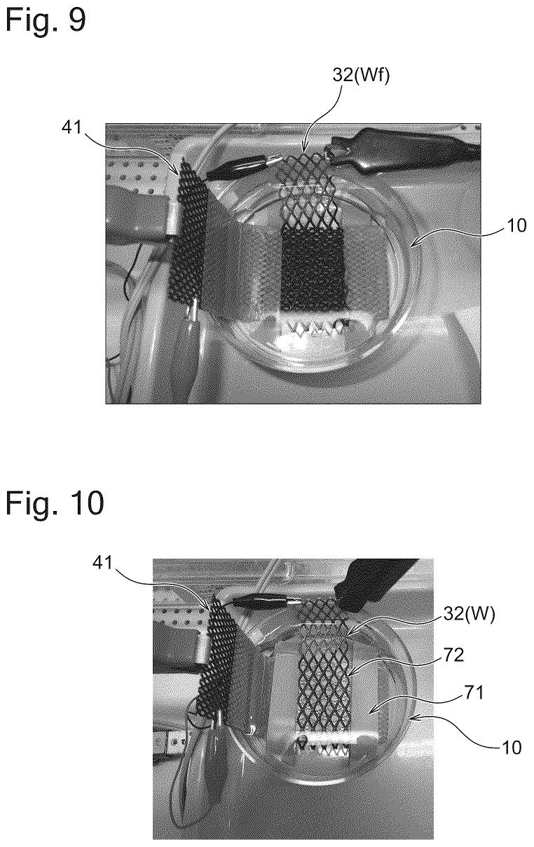

The following describes experimental examples employing the configuration of the above embodiment. FIG. 9 is a photograph showing a plating module for experiment (without a barrier membrane). FIG. 10 is a photograph showing a plating module for experiment (with a barrier membrane). FIG. 12 schematically illustrates a cross section of the plating module for experiment (with the barrier membrane) shown in FIG. 10. In FIG. 9, an anode 41 and a cathode 32 (corresponding to the substrate Wf), which is arranged above the anode 41 to be separated from the anode 41 by a predetermined distance, are placed in a plating tank 10 that stores a plating solution therein. In FIG. 10, an anode 41, a barrier membrane 71 brought into close contact with an upper face of the anode 41, a retainer plate 72 arranged to hold the barrier membrane 71, and a cathode 32 arranged above the retainer plate 72 to be separated from the retainer plate 72 by a predetermined distance are placed in a plating tank 10 that stores a plating solution therein. In the respective drawings, the anode 41 is connected with a positive electrode terminal of a power source 95 (shown in FIG. 12), and the cathode 32 is connected with a negative electrode terminal of the power source 95. The configuration of FIG. 9 omits the barrier membrane 71 and the retainer plate 72 from the configuration shown in FIG. 12.

In FIG. 12, a reference sign 95 represents a power source used to apply a voltage between an anode and a cathode, and reference signs 91 and 92 represent clamp pieces. As shown in this drawing, in the plating module for experiment (with the barrier membrane), the anode 41, the barrier membrane 71 and the retainer plate 72 are brought into close contact with each other by the clamps 91 and 92, and the cathode 32 is placed above the retainer plate 72 to be separated from the retainer plate 72 by a predetermined distance in the plating tank 10. The configuration of FIG. 12 with omission of the barrier membrane 71 and the retainer plate 72 is substantially equivalent to the configuration of the plating module for experiment (without the barrier membrane) shown in FIG. 9.

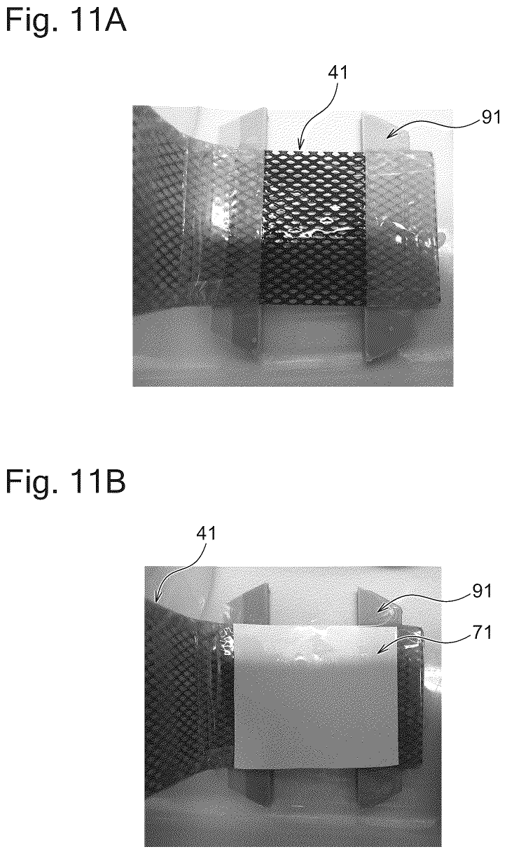

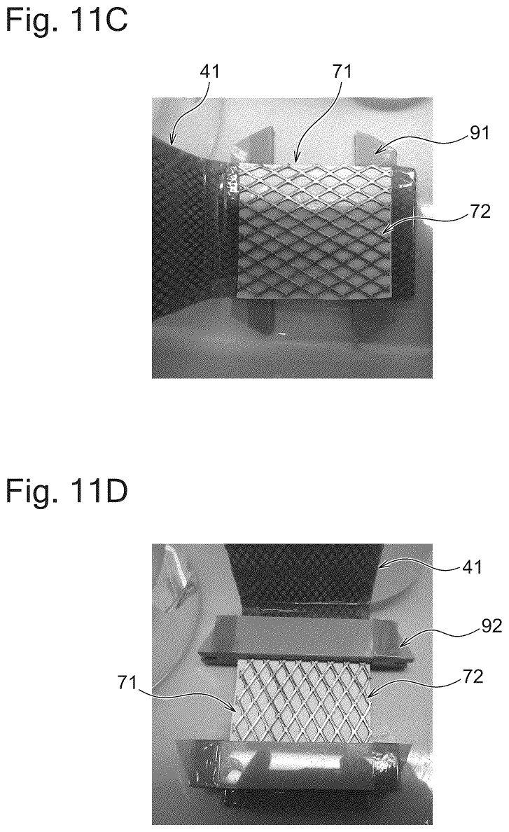

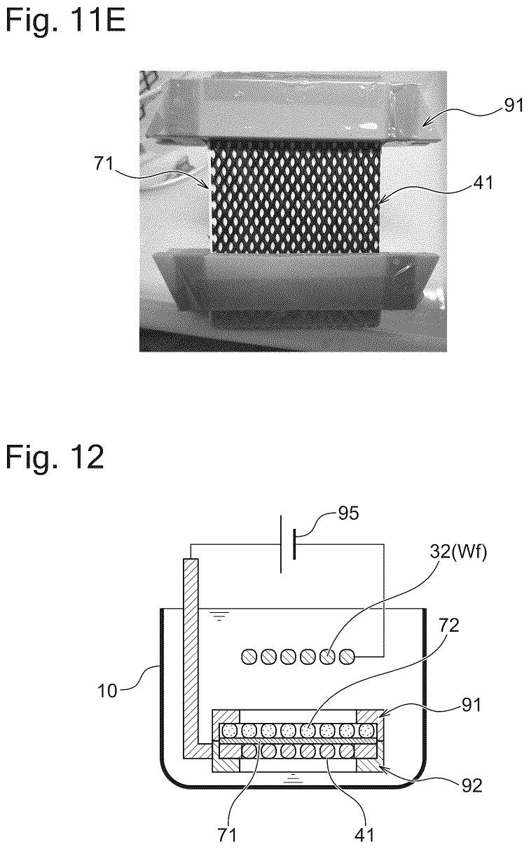

FIGS. 11A to 11E are photographs illustrating a procedure of assembling a plating module for experiment (with a barrier membrane). In FIG. 11A, the procedure places an anode 41 on a pair of clamp pieces 91. The anode 41 and the clamp pieces 91 are fixed to each other, for example, by means of a tape or the like. In FIG. 11B, the procedure places a barrier membrane 71 on an upper face of the anode 41. In FIG. 11C, the procedure places a retainer plate 72 on the barrier membrane 71. In FIG. 11D, the procedure places a pair of clamp pieces 92 on the retainer plate 72 and fixes the clamp pieces 91 and the clamp pieces 92 to each other by means of a tape or the like, so as to place the anode 41, the barrier membrane 71 and the retainer plate 72 between the clamp pieces 91 and 92 and fix the anode 41, the barrier membrane 71 and the retainer plate 72 to each other. FIG. 11E is a photograph showing the state of FIG. 11D, viewed from the bottom. The cathode 32 is subsequently placed above the retainer plate 72 to be separated from the retainer plate 72 as shown in FIG. 10. The cathode 32 is separated from the retainer plate 72 by the buoyance of a plating solution. The cathode 32 may, however, be appropriately placed on a spacer or the like to be separated from the retainer plate 72.

In the plating module for experiment (without the barrier membrane), the anode 41 is placed in the plating tank 10, and the cathode 32 is placed above the anode 41 to be separated from the anode 41, as shown in FIG. 9. The cathode 32 is separated from the retainer plate 72 by the buoyance of the plating solution. The cathode 32 may, however, be appropriately placed on a spacer or the like to be separated from the retainer plate 72.

Respective parameters used for the experiment are given below. In the experiment, an electrolytic solution free of metal ions was used in place of the plating solution, with a view to facilitating observation of generation of bubbles at the anode. An electrode reaction at the anode in the experiment was identical with the electrode reaction at the anode in the case of using the plating solution. The following shows the anode, the cathode, the electrolytic solution (plating solution), the anode area serving as the anode opposed to the cathode and the current density:
Anode: lath (wire net) of IrO2/Ti
Cathode: lath (wire net) of Pt/Ti
Barrier membrane: Yumicron Y09207TA (micro-porous membrane) (manufactured by Yuasa Membrane Systems Co., Ltd.)
Electrolytic solution: 100 g/L of H2SO4
Anode area: 0.24 dm2 (60 mm 40 mm)
Current density: 5ASD

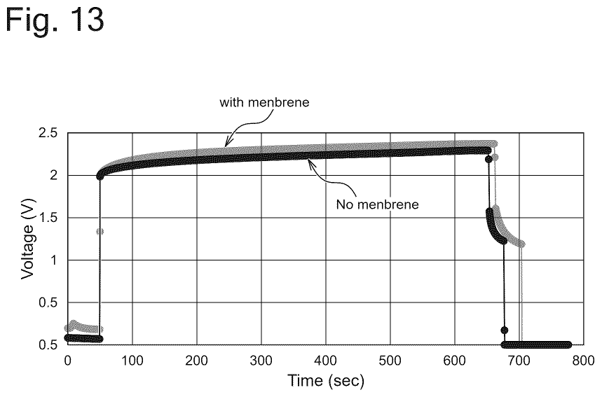

FIG. 13 shows results of measurement of an anode voltage in the course of plating. These results of the experiment show that the voltage at the anode 41 during electric conduction is stable even in the case of using the barrier membrane 71 and a variation in voltage in the case of using the barrier membrane 71 is similar to a variation in voltage in the case of using no barrier membrane. From these results, it is expected that the voltage between the anode and the cathode has a normal variation to perform a normal plating process even in the presence of the barrier membrane 71 brought into close contact with the anode 41.

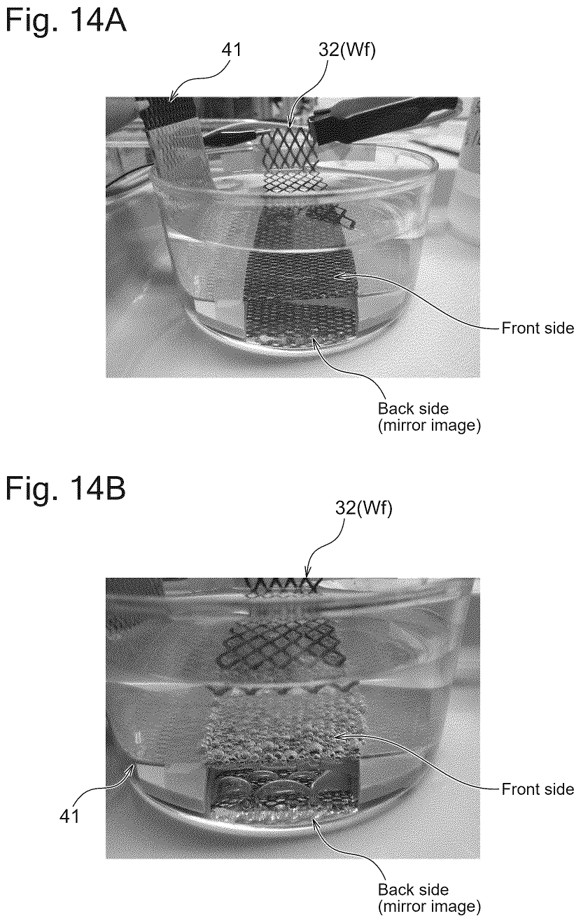

FIG. 14A is a photograph showing a plating module (without a barrier membrane) prior to plating. FIG. 14B is a photograph showing the plating module (without the barrier membrane) in the course of plating. As observed in these photographs, the plating module (without the barrier membrane) causes a large volume of bubbles generated at the anode 41 to be accumulated both above and below the anode 41. This configuration is expected to have adverse effects on the uniformity in the thickness of the plating film, due to accumulation of a large volume of bubbles between the anode 41 and the cathode 32 serving as the ion conductive path.

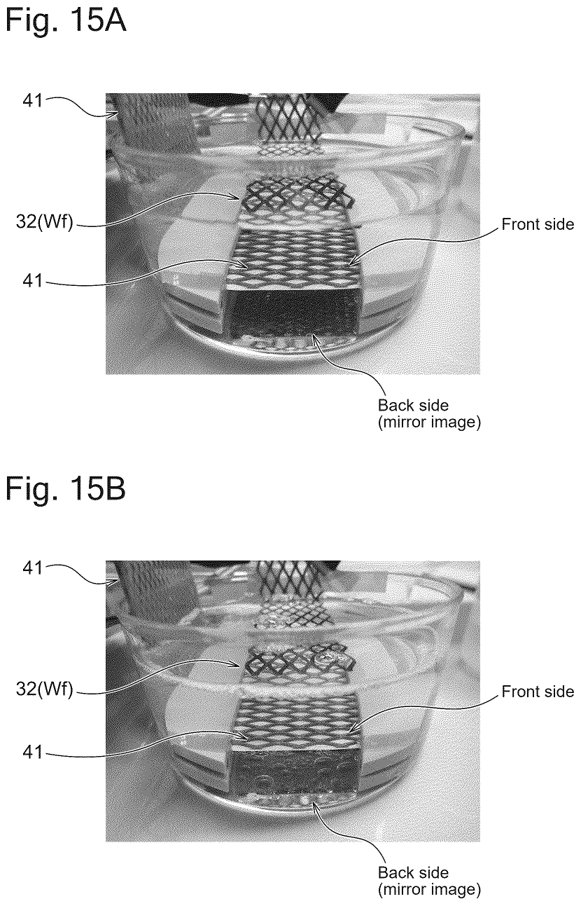

FIG. 15A is a photograph showing a plating module (with a barrier membrane) prior to plating. FIG. 15B is a photograph showing the plating module (with the barrier membrane) in the course of plating. As observed in these photographs, the plating module with the barrier membrane causes bubbles generated at the anode 41 to be present below the anode 41 but suppresses accumulation of bubbles between the anode 41 and the cathode 32 serving as the ion conductive path. Accordingly, this configuration is expected to enhance the uniformity in the thickness of the plating film.

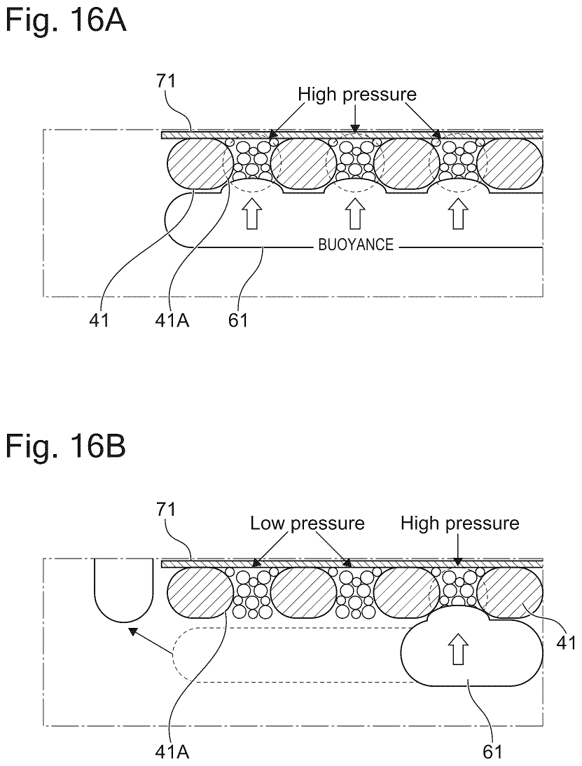

FIG. 16A and FIG. 16B are schematic diagrams illustrating movement of bubbles generated from the anode. As described above, when bubbles are accumulated on a rear face of the anode 41 (a face on a side farther from a substrate), the voltage at the anode 41 is likely to vary due to the bubbles. This phenomenon tends to notably appear, especially when plating is performed at a high current density by using a Nafion (registered trademark) membrane as an ion exchange membrane for the barrier membrane. The following two factors are possible causes of this phenomenon. The first factor is that bubbles accumulated on the rear face of the anode 41 block wraparound or sneaking of an electric field to a rear face side of the anode 41. This factor occurs even in a configuration that a barrier membrane is not brought into close contact with a front face (a substrate side-face) of the anode. This factor is thought to have small effects on the variation in the voltage at the anode. The second factor is that an increase in pressure of the plating solution (including bubbles) in the through holes of the anode due to the buoyance of bubbles accumulated on the rear face of the anode increases the pressure of the plating solution in the vicinity of the surface of the anode (the inner wall of the through holes and the rear face) and increases the saturated dissolved oxygen concentration in the plating solution, so as to increase an electrode potential of the anode.

As shown in FIG. 16A, bubbles 61 generated at the anode 41 form a layer or a mass of the bubbles 61 (hereinafter simply referred to as bubble layer) on the rear face of the anode 41. In this state, the buoyance of the bubble layer on the rear face of the anode increases the pressure of the plating solution (including bubbles) in through holes 41A. When part of the bubble layer on the rear face of the anode 41 is then separated from the rear face of the anode 41 and is discharged toward the discharge outlet 11 as shown by a broken line in FIG. 16B, no bubble layer is temporarily present on the rear face of the anode 41 in a location where part of the bubble layer is separated from the rear face of the anode 41 (the location shown by the broken line). The plating solution (including bubbles) in the through holes of the anode is accordingly released from the buoyance by the bubble layer on the rear face of the anode. As a result, this decreases the pressure of the plating solution in the through holes of the anode and lowers the saturated dissolved oxygen concentration in the vicinity of the surface of the anode (the inner wall of the through holes and the rear face), so as to decrease the electrode potential of the anode 41. A bubble layer is subsequently formed again in the location shown by the broken line. Such a variation in the pressure of the plating solution in the vicinity of the surface of the anode (the inner wall of the through holes and the rear face), however, causes a variation in the saturated dissolved oxygen concentration in the vicinity of the surface of the anode (the inner wall of the through holes and the rear face) and a resulting variation in the voltage of the anode 41 and is thus likely to reduce the in-plane uniformity in the thickness of the plating film.

### Third Embodiment

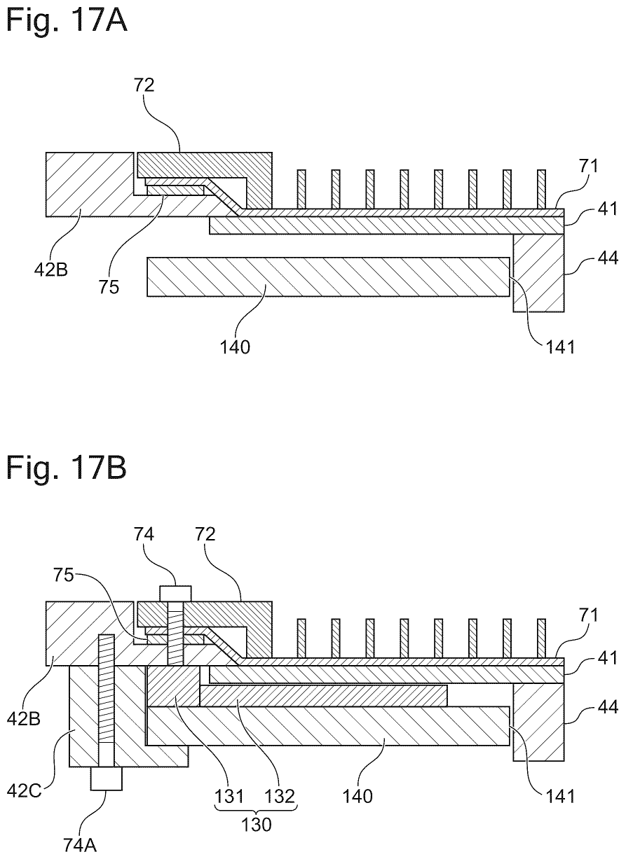

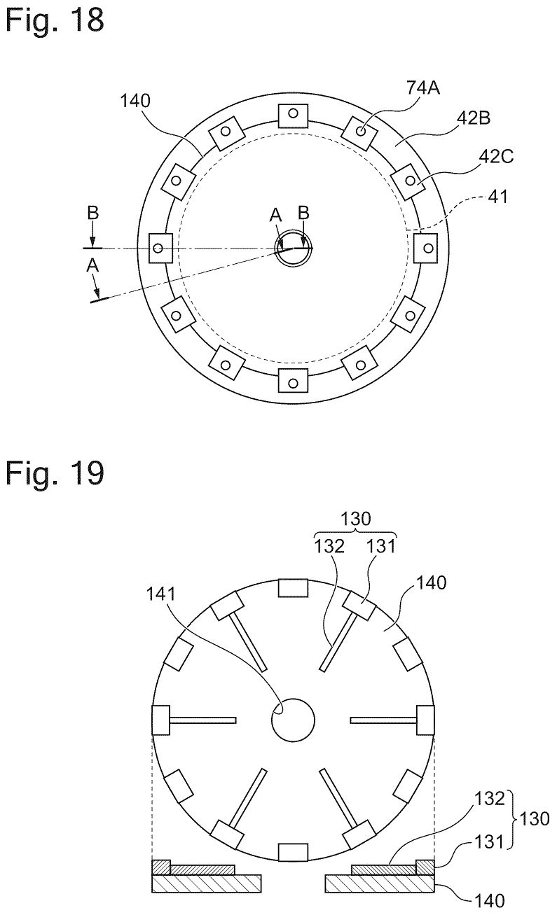

FIG. 17A, FIG. 17B and FIG. 18 illustrate the structure in the vicinity of an anode in a plating module according to a third embodiment. FIG. 18 is a bottom view illustrating the structure in the vicinity of the anode, viewed from the bottom. FIG. 17A is a sectional view taken along a line A-A in FIG. 18, and FIG. 17B is a sectional view taken along a line B-B in FIG. 18. FIG. 19 is a plan view and a sectional view illustrating a bubble regulating plate. The following mainly describes a configuration different from those of the above embodiments with omitting the description on the configuration similar to those of the above embodiments.

According to this embodiment, as shown in FIG. 17A and FIG. 17B, a bubble regulating plate 140 (also referred to as a rear face plate) is placed below an anode 41 across a predetermined interval or gap (for example, an interval of not greater than 5 mm or more preferably an interval of not greater than 2 mm). As shown in FIG. 19, the bubble regulating plate 140 has a similar shape (a circular shape in the illustrated example) to the shape of the anode 41 and has a larger diameter than the diameter of the anode 41 such as to cover the entirety of a rear face of the anode 41. A through hole 141 is provided in the center of the bubble regulating plate 140 such as to allow a power feed boss 44 to pass therethrough. As shown in FIG. 17A and FIG. 17B, spacers 130 are provided between the anode 41 and the bubble regulating plate 140 such as to adjust an interval between the anode 41 and the bubble regulating plate 140. As shown in FIG. 19, the spacers 130 may be attached in advance to an upper face of the bubble regulating plate 140 by means of an adhesive or the like. The spacers 130 include a plurality of circumferential direction spacers 131 arranged at equal intervals along an outer circumference of the bubble regulating plate 140 and a plurality of radial direction spacers 132 integrated with or attached to part of the circumferential direction spacers 131. In this illustrated example, the radial direction spacers 132 are provided in every other peripheral direction spacers 131. The radial direction spacers 132 may be integrated with the circumferential direction spacers 131 or may be linked with or brought into contact with the circumferential direction spacers 131.

According to the embodiment, as shown in FIG. 17B and FIG. 18, an anode holder 42 includes a ring-shaped upper anode retainer 42B and a plurality of lower anode retainers 42C arranged along a circumferential direction of the upper anode retainer 42B. The upper anode retainer 42B is integrated with a side wall of the plating tank 10 or may be attached to the side wall of the plating tank 10. The upper anode retainer 42B comes into contact with an outer circumferential part of an upper face of the anode 41 to hold the anode 41. A barrier membrane 71, a seal 75 and a retainer plate 72 are fixed to an upper face of the upper anode retainer 42B by means of a fastening member 74. In other words, the retainer plate 72 is fixed to the upper anode retainer 42B in such a state that the retainer plate 72 presses down the barrier membrane 71 and the seal 75. The plurality of lower anode retainers 42C are fixed to a lower face of the upper anode retainer 42B by means of fastening members 74A. The respective lower anode retainers 42C are provided corresponding to the circumferential direction spacers 131.

The upper anode retainer 42B and the lower anode retainers 42C serve to fix the anode 41, the spacers 130 and the bubble regulating plate 140 that are placed between the upper anode retainer 42B and the lower anode retainers 42C in a vertical direction. More specifically, the respective lower anode retainers 42C are fixed to the upper anode retainer 42B by means of the fastening members 74A, such that the bubble regulating plate 140 and the circumferential direction spacers 131 are placed between the lower anode retainers 42C and the upper anode retainer 42B. Accordingly, the anode 41 and the radial direction spacers 132 are placed and fixed between the upper anode retainer 42B and the bubble regulating plate 140. In the state that the bubble regulating plate 140 is mounted in the vicinity of the anode 41 as described above, the radial direction spacers 132 are placed between the bubble regulating plate 140 and the anode 41, and the circumferential direction spacers 131 are placed between the bubble regulating plate 140 and the upper anode retainer 42B, as shown in FIG. 17B. The interval between the anode 41 and the bubble regulating plate 140 is accordingly set by the radial direction spacers 132.

In locations where the circumferential direction spacers 131 are not placed on the bubble regulating plate 140 (areas of the bubble regulating plate 140 between the circumferential direction spacers shown in FIG. 19), the space between the anode 41 and the bubble regulating plate 140 is open radially outward as shown in FIG. 17A.

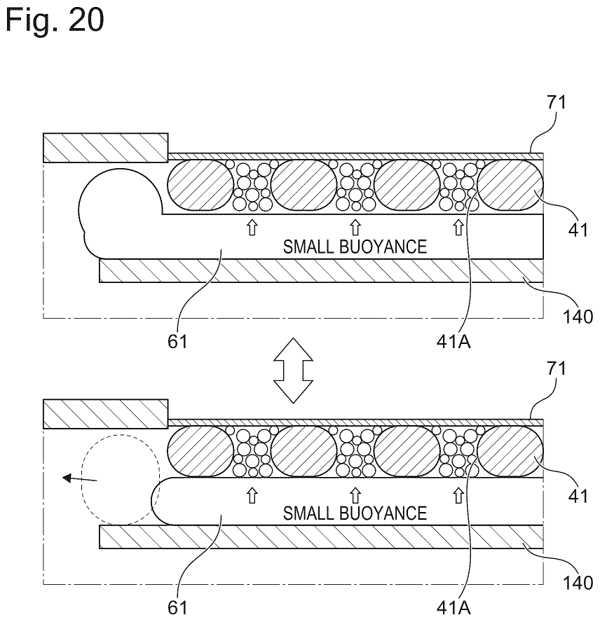

FIG. 20 is schematic diagrams illustrating discharge of bubbles on the rear face of the anode according to the third embodiment. According to this embodiment, the bubble regulating plate 140 is present on the rear face of the anode 41. Accumulation of bubbles 61 on the rear face of the anode 41 is accordingly limited to within the interval between the anode 41 and the bubble regulating plate 140 as shown in these drawings. This configuration causes only a small amount of accumulation of the bubbles on the rear face of the anode 41 (limits the thickness of a layer of the bubbles 61). Even when the bubbles 61 are released from the anode 41 to be discharged as shown by a broken line part in the lower drawing of FIG. 20, this configuration has a small change in the amount of accumulation of the bubbles on the rear face of the anode 41. As shown in FIG. 20, the release of the bubbles is likely to occur on an outer side of the rear face of the anode 41. This configuration suppresses a pressure change in the vicinity of the surface of the anode (the inner wall of the through holes and the rear face) and suppresses a variation in the saturated dissolved oxygen concentration in the plating solution in the vicinity of the surface of the anode (the inner wall of the through holes and the rear face) and a resulting variation in the electrode voltage of the anode, thus suppressing reduction of the in-plane uniformity in the thickness of the plating film. With a view to decreasing the amount of accumulation of bubbles on the rear face of the anode 41, it is preferable that the interval between the anode 41 and the bubble regulating plate 140 (corresponding to the thickness of the radial direction spacers 132) is smaller than the height of bubbles that are accumulated on the rear face of the anode 41 in a configuration without the bubble regulating plate 140. The height of the bubbles formed depends on the surface tension and the specific gravity of the plating solution used. The interval between the anode 41 and the bubble regulating plate 140 is, however, generally not greater than 5 mm and is more preferably not greater than 2 mm.

The spaces between the circumferential direction spacers 131 and/or between the radial direction spacers 132 are arranged at equal intervals in the circumferential direction, so that the bubbles 61 on the rear face of the anode 41 are equally discharged in the circumferential direction. This configuration enables the bubbles on the rear face of the anode 41 to be evenly released from the anode 41 and further reduces a change in the amount of accumulation of the bubbles. This also reduces the unevenness in the amount of accumulation of bubbles in the respective locations on the rear face of the anode. Moreover, a plurality of discharge outlets 11 may be provided. For example, the discharge outlet 11 may be provided in every area between the adjacent radial direction spacers 132.

Furthermore, the plurality of radial direction spacers 132 arranged at equal intervals serve to appropriately divide the space between the anode 41 and the bubble regulating plate 140. This suppresses release of a large mass of bubbles.

### (Modifications)

In the embodiment described above, the spacers 130 (131 and 132) are in a rectangular prism shape. The shape and the dimensions of the spacers are, however, not limited, as long as the shape and the dimensions define a predetermined interval (gap) between the anode 41 and the bubble regulating plate 140 and do not interfere with discharge of bubbles. For example, the spacers may be in a columnar shape, in a triangular prism shape and/or in a disk shape. In another example, pin-type spacers that pass through the bubble regulating plate 140 to come into contact with the rear face of the anode 41 may be employed to define a predetermined gap between the anode and the bubble regulating plate (as described below). These spacers may, however, be omitted in the case where the anode 41 and the bubble regulating plate 140 have sufficient degrees of flatness to define a predetermined gap without using the spacers 132 or spacers 132A (described below).

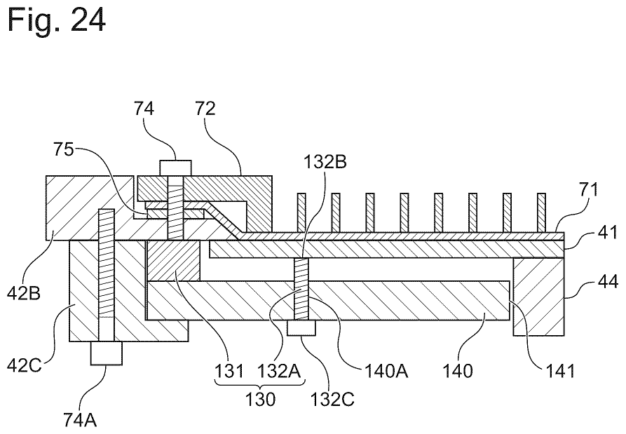

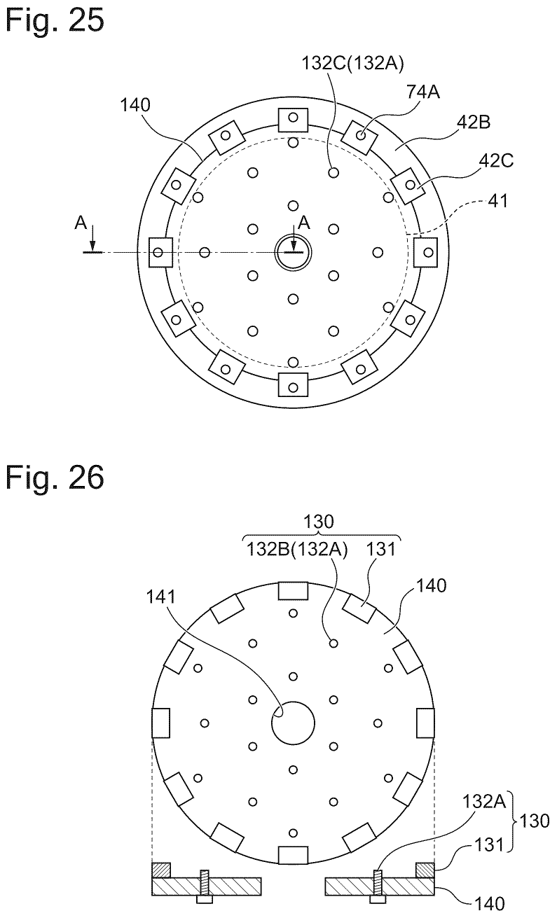

FIG. 24 and FIG. 25 illustrate the structure in the vicinity of an anode in a plating module according to a modification. FIG. 25 is a bottom view illustrating the structure in the vicinity of the anode, viewed from the bottom, and FIG. 24 is a sectional view taken along a line A-A in FIG. 25. FIG. 26 is a plan view and a sectional view illustrating a bubble regulating plate. The following mainly describes a configuration different from that of the above embodiment with omitting the description on the configuration similar to that of the above embodiment. As shown in these drawings, the configuration of the modification differs from the configuration of the above embodiment by replacement of the radial direction spacers 132 with pin-type spacers 132A. For example, the pin-type spacer 132A is a screw-type spacer and has a threaded side face, a flat or curved leading end 132B that comes into contact with the rear face of the anode 41, and a screw head 132C on a base end side thereof. In this modification, through holes (threaded holes) 140A are formed in a bubble regulating plate 140 by thread cutting. The pin-type spacer 132A is screwed upward into the through hole 140A to be protruded upward, so that the leading end of the pin-type spacer 132A is brought into contact with the rear face of the anode 41. This accordingly defines a predetermined interval (gap) between the anode 41 and the bubble regulating plate 140. In another example, the pin-type spacers 132A may be fixed to the bubble regulating plate 140 by any other means, instead of formation of threads in the pin-type spacers 132A and the bubble regulating plate 140.

### Fourth Embodiment

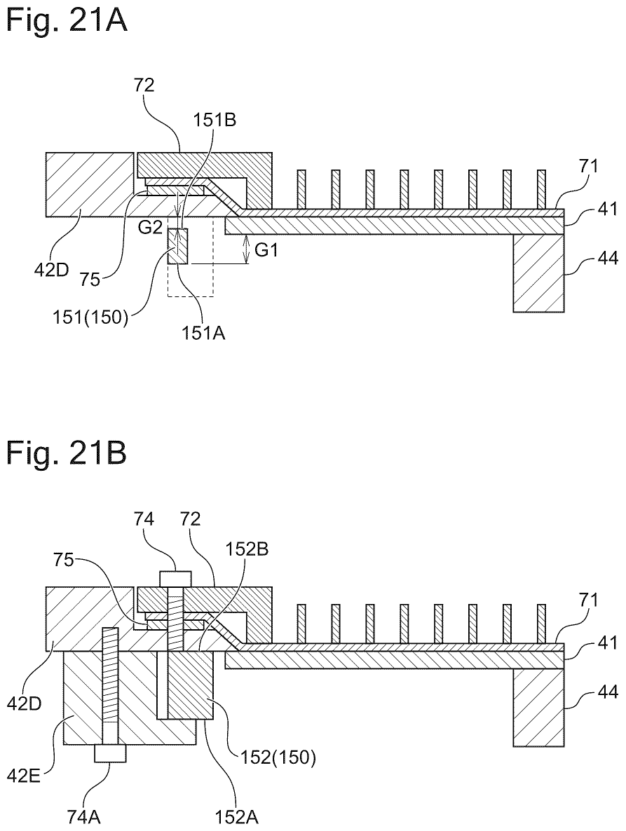

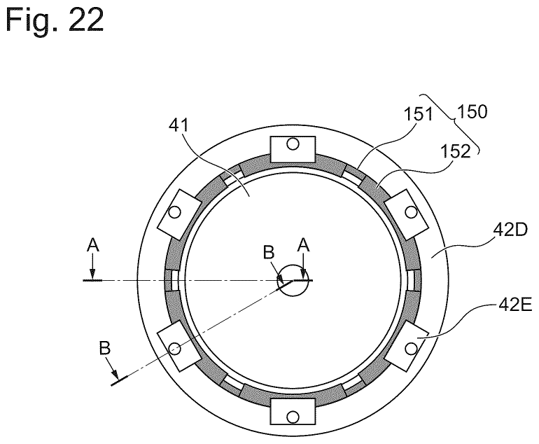

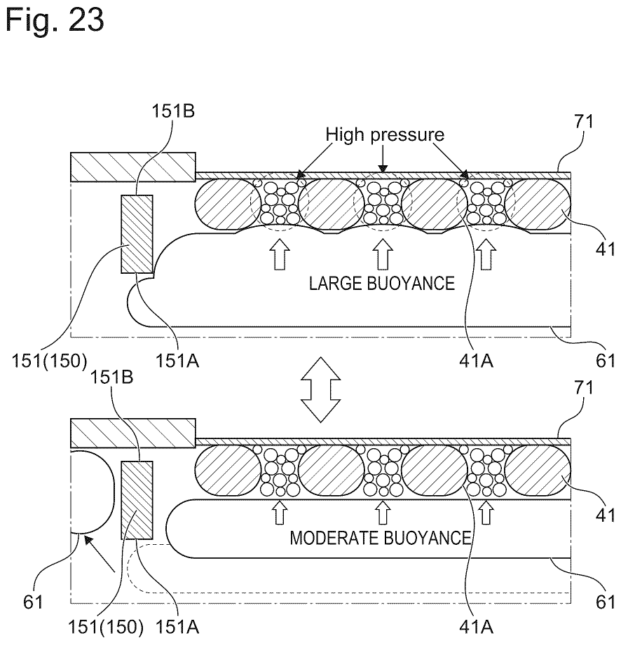

FIG. 21A, FIG. 21B and FIG. 22 illustrate the structure in the vicinity of an anode in a plating module according to a third embodiment. FIG. 22 is a bottom view illustrating the structure in the vicinity of the anode, viewed from the bottom. FIG. 21A is a sectional view taken along a line A-A in FIG. 22, and FIG. 21B is a sectional view taken along a line B-B in FIG. 22. FIG. 23 is schematic diagrams illustrating discharge of bubbles on a rear face of an anode. The following mainly describes a configuration different from those of the above embodiments with omitting the description on the configuration similar to those of the above embodiments.

According to the embodiment, as shown in FIG. 21A, FIG. 21B and FIG. 22, a bubble buffer ring 150 is placed to surround the periphery of the anode 41. The bubble buffer ring 150 has a plurality of smaller diameter portions 151 and a plurality of larger diameter portions 152, both having rectangular cross sections. As shown in FIG. 22, the smaller diameter portions 51 and the larger diameter portions 52 are arranged alternately along a circumferential direction of the bubble buffer ring 150. As shown in FIG. 21A and FIG. 21B, the smaller diameter portions 151 are formed to have a smaller width (dimension in a radial direction) and a smaller thickness (dimension in a height direction) than those of the larger diameter portions 152. Lower end faces 151A of the smaller diameter portions 151 are placed at positions higher than the positions where lower end faces 152A of the larger diameter portions 152 are placed. A gap G1 that is a height difference between the lower end faces 151A of the smaller diameter portions 151 and a rear face of the anode 41 defines the thickness of a layer of bubbles 61 accumulated on the rear face of the anode 41 (as shown in FIG. 23). An excess part of the layer of the bubbles 61 accumulated over the gap G1 on the rear face of the anode 41 is released and discharged across the lower end faces 151A of the smaller diameter portions 151 of the bubble buffer ring 150 to an outer side in the radial direction. Upper end faces 151B of the smaller diameter portions 151 are placed below upper end faces 152B of the larger diameter portions 152. A gap G2 is formed between an anode retainer 42D and the upper end faces 151B of the smaller diameter portions 151. The gap G2 is a gap for penetration of the plating solution and serves to allow the plating solution to be penetrated into an anode 41-side. The anode retainer 42D has a similar configuration to that of the anode retainer 42B described above.

As shown in FIG. 22, a plurality of retainer members 42D fixed to the ring-shaped anode retainer 42E are provided along a circumferential direction of the anode retainer 42D. Each of the retainer members 42E is provided corresponding to each of the large diameter portions 152 of the bubble buffer ring 150. In the illustrated example, each retainer member 42E is placed at the center in a longitudinal direction along a circumferential direction of the large diameter portion 152. The anode retainer 42D and the retainer members 42E are fixed by means of fastening members 74A in such a state that the large diameter portions 152 of the bubble buffer ring 150 are placed between the anode retainer 42D and the retainer members 42E. The bubble buffer ring 150 is accordingly attached to the plating tank 10 such as to surround the periphery of the anode 41. The anode 41 is placed at a predetermined height, for example, by a non-illustrated member such as a spacer, provided below a power feed boss 44, and an outer circumferential part of the anode 41 is pressed down by the anode retainer 42D, so that the anode 41 is fixed in the vertical direction.

FIG. 23 is a schematic diagram illustrating discharge of bubbles on the rear face of the anode according to the fourth embodiment. According to this embodiment, an excess part of the bubbles 61 accumulated over the lower end faces 151A of the small diameter portions 151 of the bubble buffer ring 150 on the rear face of the anode 41 is released and discharged across the lower ends of the small diameter portions 151 to an outer side in the radial direction, as shown by a broken line in the lower drawing of FIG. 23. In this configuration, an excess part of the bubbles 61 exceeding the lower end faces 151A of the small diameter portions 150 of the bubble buffer ring 150 is released, and it is expected that a slightly large amount of the bubbles is released at one time. A layer or a mass of the bubbles 61 is, however, continuously accumulated over the entire rear face of the anode 41. This configuration accordingly suppresses a pressure change in the vicinity of the surface of the anode (the inner wall of the through holes and the rear face). This suppresses a variation in the saturated dissolved oxygen concentration in the plating solution in the vicinity of the surface of the anode (the inner wall of the through holes and the rear face) and a resulting variation in the electrode voltage of the anode, thus suppressing reduction of the in-plane uniformity in the thickness of the plating film.

The configurations of the embodiments described above have at least the following functions and advantageous effects.

(1) The configurations of the embodiments described above suppress the bubbles (resistive component) from being accumulated on the ion conductive path between the anode and the substrate and from affecting the uniformity in the thickness of the plating film. These configurations also enable the cation to be conducted through the barrier membrane brought into close contact with/adhering to the anode, to the substrate side. This certainly provides the ion conductive path between the anode and the substrate, while avoiding the effects of the bubbles. This accordingly ensures stable plating on the substrate, while suppressing an ion conductive resistance from being generated on the ion conductive path between the anode and the substrate by the bubbles from the anode, thus enhancing the uniformity in the thickness of the plating film.

(2) The configurations of the embodiments described above allow an insoluble anode to be used for the anode. This improves the easiness of maintenance of the anode and reduces the running cost.

(3) The configurations of the embodiments described above enable the gas generated at the anode to be naturally discharged without circulation of the plating solution in the anode chamber. This simplifies the structure and/or the operation of the plating tank. The discharge of the bubbles may further be accelerated by circulation of the plating solution in the anode chamber.

(4) In the configurations of the embodiments described above, using the bubble regulating plate or the bubble buffer ring suppresses an abrupt pressure change in the vicinity of the surface of the anode (the inner wall of the through holes and the rear face), which is caused by release of the bubbles accumulated on the rear face of the anode. This suppresses a variation in the saturated dissolved oxygen concentration in the vicinity of the surface of the anode (the inner wall of the through holes and the rear face) and a resulting variation in the electrode voltage of the anode, thus suppressing reduction of the in-plane uniformity in the thickness of the plating film.

### [Modification]

The foregoing illustrates the face down-type plating modules, but the present disclosure is also applicable to face up-type plating modules configured to plate a plating surface or a surface to be plated of a substrate that faces up.

At least the following aspects are provided from the description of the above embodiments.

[1] According to one aspect, there is provided an apparatus for plating, comprising: a plating tank configured to store a plating solution therein; an anode placed in the plating tank and provided with a plurality of through holes; a substrate holder provided to hold a substrate to be opposed to the anode; a barrier membrane placed to be brought into close contact with/adhere to a first face on a substrate side of the anode; and a rear face plate placed to be opposed to a second face of the anode that is on an opposite side to the first face and to be separated from the second face by a predetermined distance and configured to regulate an amount of bubbles generated from the anode and accumulated on the second face. A distance between the rear face plate and the anode is set to be a short distance (for example, not greater than 5 mm and more preferably not greater than 2 mm) that sufficiently decreases the amount of accumulation of the bubbles on the second face of the anode, with a view to preventing a variation in an electrode potential of the anode due to release of the bubbles accumulated on the second face of the anode.

The configuration of this aspect has the barrier membrane that is brought into close contact with the substrate side-face of the anode having the plurality of through holes. This configuration enables bubbles of a gas generated at the anode to be moved through the plurality of through holes in the anode to a second face-side of the anode, while the barrier membrane suppresses the bubbles of the gas generated at the anode from moving toward the substrate side. Using the barrier membrane brought into close contact with/adhering to the anode suppresses accumulation of the bubbles between the anode and the barrier membrane. As a result, this configuration suppresses bubbles from being accumulated on an ion conductive path between the anode and the substrate.

Furthermore, this configuration enables a cation to be moved through the barrier membrane. This certainly provides the ion conductive path between the anode and the substrate and assures a stable electrode reaction on the substrate.

As a result, this configuration suppresses bubbles from being accumulated on the ion conductive path between the anode and the substrate and certainly provides the ion conductive path between the anode and the substrate to stably perform plating of the substrate. This accordingly enhances the uniformity in a distribution of the thickness (thickness distribution) of a plating film. In other words, this configuration solves the problem in the conventional configuration that the barrier membrane is placed away from the anode, i.e., the problem that bubbles from the anode are accumulated on the barrier membrane on the ion conductive path and adversely affect the uniformity in the distribution of the thickness of the plating film.

Furthermore, in the configuration of this aspect, the presence of the rear face plate on the second face side of the anode limits the thickness of the bubbles on the second face of the anode to be within a distance between the anode and the rear face plate. This configuration reduces an amount of accumulation of the bubbles on the second face of the anode and suppresses a change in the amount of accumulation of the bubbles on the second face of the anode accompanied with discharge of the bubbles. This accordingly suppresses a pressure change of the plating solution in the vicinity of the second face of the anode and thereby suppresses a variation in the electrode potential at the anode.

[2] According to one aspect, the apparatus for plating of the above aspect may further comprise a plurality of radial direction spacers provided between the rear face plate and the anode and arranged along a circumferential direction of the anode to be extended in a radial direction between a center and an outer circumferential part of the rear face plate.

In the configuration of this aspect, a distance between the rear face plate and the anode is adjustable by the radial direction spacers. Furthermore, the plurality of radial direction spacers extended in the radial direction maintain the distance between the anode and the rear face plate. This configuration suppresses deflection of the anode and the rear face plate and enables the distance between the anode and the rear face plate to be accurately adjusted over the entire area of the anode. The radial direction spacers also serve to guide the bubbles accumulated on the second face of the anode, toward an outer side in the radial direction. Arranging the plurality of radial direction spacers at equal intervals along the entire circumference of the anode enables the bubbles along the entire circumference of the anode to be evenly discharged to the outer side in the radial direction.

[3] According to one aspect, the apparatus for plating of the above aspect may further comprise a first anode retainer configured to hold an outer circumferential part of the first face of the anode; and a plurality of circumferential direction spacers provided between the rear face plate and the first anode retainer and arranged along the circumferential direction of the anode.

The configuration of this aspect maintains the distance between the first anode retainer and the rear face plate to a desired distance and thereby stabilizes mounting of the rear face plate. Furthermore, arranging the plurality of circumferential direction spacers in a dispersed manner provides spaces for discharge of the bubbles between the circumferential direction spacers. Arranging the plurality of circumferential direction spacers at equal intervals along the entire circumference of the anode enables the bubbles along the entire circumference of the anode to be evenly discharged to the outer side in the radial direction.

[4] According to one aspect, in the apparatus for plating of the above aspect, the radial direction spacers may be provided alternately in the plurality of circumferential direction spacers.

The configuration of this aspect enables the distance between the anode and the rear face plate to be maintained with high accuracy without excessively blocking the second face side of the anode by the radial direction spacers.

[5] According to one aspect, the apparatus for plating of the above aspect may further comprise a plurality of second anode retainers configured such that the circumferential direction spacers and the rear face plate are placed and fixed between the first anode retainer and second anode retainers, wherein the second anode retainers may be provided corresponding to the circumferential direction spacers.

In the configuration of this aspect, the circumferential direction spacers and the rear face plate are placed between the first anode retainer and the second anode retainers on the outer side of the anode, so that the anode and the radial direction spacers are placed between the anode retainer and the rear face plate. Moreover, providing the plurality of second anode retainers corresponding to the circumferential direction spacers enables the circumferential direction spacers to be effectively held by the second anode retainers.

[6] According to one aspect, the apparatus for plating of the above aspect may further comprise a plurality of pin-type spacers provided to pass through the rear face plate and to come into contact with the anode.

The configuration of this aspect uses the pin-type spacers, each of which occupies a small installation area. The position and/or the number of the pin-type spacers to be installed are thus selectable with a high degree of freedom.

[7] According to one aspect, in the apparatus for plating of the above aspect, the pin-type spacer may be screwed into a threaded hole of the rear face plate, such that a leading end of the pin-type spacer comes into contact with the anode.

In the configuration of this aspect, the pin-type spacers are screw-type spacers. An interval between the anode and the rear face plate is thus readily adjustable according to the degree of screwing into the rear face plate.

[8] According to one aspect, there is provided an apparatus for plating comprising: a plating tank configured to store a plating solution therein; an anode placed in the plating tank and provided with a plurality of through holes; a substrate holder provided to hold a substrate to be opposed to the anode; a barrier membrane placed to be brought into close contact with/adhere to a first face on a substrate side of the anode; and a bubble buffer ring provided to surround the anode and configured to have an end face that is placed at a position of a predetermined height in a direction farther from a second face of the anode, which is on an opposite side to the first face, and that regulates an amount of bubbles generated from the anode and accumulated on the second face.

Similarly to the configuration of the aspect [1] described above, the configuration of this aspect suppresses bubbles from being accumulated on an ion conductive path between the anode and the substrate and certainly provides the ion conductive path between the anode and the substrate to stably perform plating of the substrate. This accordingly enhances the uniformity in the distribution of the thickness of the plating film.

Furthermore, with regard to the bubbles accumulated on the second face of the anode, this configuration enables the bubbles to be continuously accumulated on the second face of the anode up to the height of the end face of the bubble buffer ring and to be continuously present over the entire second face of the anode. This configuration suppresses a change in the amount of accumulation of the bubbles on the second face of the anode accompanied with discharge of the bubbles. This accordingly suppresses a pressure change of the plating solution in the vicinity of the second face of the anode and thereby suppresses a variation in the electrode potential at the anode.

[9] According to one aspect, the apparatus for plating of the above aspect may further comprise an anode retainer configured to hold an outer circumferential part of the first face of the anode, wherein a predetermined clearance may be formed between the bubble buffer ring and the anode retainer on an outer side of the anode.

The configuration of this aspect enables the plating solution to be penetrated to the anode side via the clearance between the anode retainer and the bubble buffer ring.

According to one aspect, in the apparatus for plating of the above aspect, the bubble buffer ring may include a plurality of first portions having a first thickness and a plurality of second portions thicker than the first thickness, wherein the first portions and the second portions may be arranged alternately in a circumferential direction of the bubble buffer ring. In a state that the second portions are brought into contact with the anode retainer, end faces of the first portions on a side farther from the substrate may form the end face that regulates the amount of the bubbles, and the predetermined clearance may be formed between the anode retainer and end faces of the first portions on a side nearer to the substrate.

The configuration of this aspect enables the bubble buffer ring having the end face that regulates the amount of bubbles and the end face that forms the clearance for penetration of the plating solution to be provided by the simple configuration.

According to one aspect, the apparatus for plating of the above aspect may further comprise a second retainer member configured such that the second portions of the bubble buffer ring are placed and fixed between the anode retainer and the second retainer member.

In the configuration of this aspect, the second portions (thicker wall portions) of the bubble buffer ring are placed and fixed between the anode retainer and the second retainer member. This configuration thus enables the first portions of the bubble buffer ring to form the end face that regulates the amount of bubbles and the end face that forms the clearance for penetration of the plating solution.

According to one aspect, the apparatus for plating of the above aspect may be configured such that a pressure of the plating solution in a cathode chamber that is on a substrate side of the barrier membrane becomes higher than a pressure of the plating solution in an anode chamber that is on an anode side of the barrier membrane, wherein the barrier membrane may be pressed against a substrate side-face of the anode by the pressure of the plating solution in the cathode chamber.

The configuration of this aspect causes the barrier membrane to be pressed against the anode by a pressure difference between the cathode chamber and the anode chamber and improves the contact/adhesion property over the entire face of the barrier membrane.

According to one aspect, in the apparatus for plating of the above aspect, the plating tank may be provided with a discharge outlet that is formed to communicate with the anode chamber and that is configured to discharge bubbles from the anode chamber to outside of the plating tank.

The configuration of this aspect enables the bubbles generated at the anode to be naturally discharged through the discharge outlet.

According to one aspect, in the apparatus for plating of the above aspect, a side wall of the plating tank may have a height set, such that an overflow surface of the plating solution in the cathode chamber is higher than an overflow surface of the plating solution in the discharge outlet.

In the configuration of this aspect, the height of the side wall of the plating tank is set, such that the overflow surface in the cathode chamber is higher than the overflow surface in the anode chamber. This simple configuration provides a pressure difference between the cathode chamber and the anode chamber.

According to one aspect, in the apparatus for plating of the above aspect, the barrier membrane may be arranged to be pressed against a substrate side-face of the anode by a retainer plate having a plurality of through holes.

The configuration of this aspect provides an ion conductive path through the plurality of holes in the retainer plate and causes the entire barrier membrane to be pressed against the anode, so as to improve the contact/adhesion property.

According to one aspect, in the apparatus for plating of the above aspect, a seal may be provided in an outer circumferential part of the barrier membrane to seal between the retainer plate and the barrier membrane.

The configuration of this aspect effectively prevents communication between the anode chamber and the cathode chamber at a location other than the barrier membrane.

According to one aspect, in the apparatus for plating of the above aspect, the barrier membrane may be joined with a substrate side-face of the anode.

The configuration of this aspect joins the barrier membrane with the anode and thereby certainly enables the barrier membrane to be brought into close contact with/adhere to the anode.

According to one aspect, in the apparatus for plating of the above aspect, the barrier membrane may be joined with the substrate side-face of the anode via a joint layer (adhesive layer) having ion permeability.

The configuration of this aspect joins the barrier membrane with the anode and thereby certainly enables the barrier membrane to be brought into close contact with/adhere to the anode. This configuration also certainly provides an ion conductive path from the anode to the substrate via the joint layer having ion permeability.

According to one aspect, the apparatus for plating of the above aspect may further comprise a retainer ring configured to hold an outer circumferential part of the barrier membrane; and a seal configured to seal between the retainer ring and the barrier membrane.

The configuration of this aspect effectively prevents communication between the anode chamber and the cathode chamber at a location other than the barrier membrane.

According to one aspect, in the apparatus for plating of the above aspect, the anode may be an insoluble anode. The configuration of this aspect suppresses bubbles of a gas generated at the insoluble anode in the course of plating from adversely affecting the uniformity in the distribution of the thickness of the plating film. Using the insoluble anode improves the easiness of maintenance of the apparatus for plating and reduces the running cost.

According to one aspect, in the apparatus for plating of the above aspect, the substrate holder may hold the substrate in such a state that a plating surface or a surface to be plated of the substrate faces down, and the anode may be placed below the substrate and is opposed to the substrate. The configuration of this aspect suppresses adverse effects of bubbles of a gas generated at the anode in the course of plating, on the uniformity in the distribution of the thickness of the plating film, in a face down-type apparatus for plating configured such that the anode faces up to be opposed to the substrate.

According to one aspect, there is provided a method of plating a substrate. The method comprises providing the apparatus for plating described in any one of the above aspects [1] to [21]; and plating the substrate by using the apparatus for plating.

Although the embodiments of the present invention have been described based on some examples, the embodiments of the invention described above are presented to facilitate understanding of the present invention, and do not limit the present invention. The present invention can be altered and improved without departing from the subject matter of the present invention, and it is needless to say that the present invention includes equivalents thereof. In addition, it is possible to arbitrarily combine or omit the embodiments and the modifications described above and it is also possible to arbitrarily combine or omit respective constituent elements described in the claims and the specification in a range where at least a part of the above-mentioned problem can be solved or a range where at least a part of the effect is exhibited.

The entire disclosure of US Patent Application Publication No. 2020-0017989 (PTL 1) including the specification, claims, drawings and abstract is incorporated herein by reference in its entirety.

### REFERENCE SIGNS LIST

10 plating tank
10a overflow weir
10c overflow weir
11 discharge outlet
20 overflow weir
31 substrate holder
41 anode
41A through hole
42 anode holder
42A cut
42B upper anode retainer
42C lower anode retainer
42D anode retainer
42E retainer member
43 anode mask
51 resistor
61 bubble
71 barrier membrane
72 retainer plate
72A through hole
74 fastening member
75 seal
80 circulation path
81 pump
130 spacer
131 circumferential direction spacer
132 radial direction spacer
140 bubble regulating plate (rear face plate)
141 through hole
150 bubble buffer ring
151 small diameter portion
151A lower end face
151B upper end face
152 large diameter portion
152A lower end face
152B upper end face
400 plating module
Ca anode chamber
Cc cathode chamber
Sa, Sc overflow surfaces

1. An apparatus for plating, comprising:
a plating tank configured to store a plating solution therein;
an anode placed in the plating tank and provided with a plurality of through holes;
a substrate holder provided to hold a substrate to be opposed to the anode;
a barrier membrane placed to be brought into close contact with a first face on a substrate side of the anode; and
a rear face plate placed to be opposed to a second face of the anode that is on an opposite side to the first face and to be separated from the second face by a predetermined distance and configured to regulate an amount of bubbles generated from the anode and accumulated on the second face.

2. The apparatus for plating according to claim 1, further comprising:
a plurality of radial direction spacers provided between the rear face plate and the anode and arranged along a circumferential direction of the anode to be extended in a radial direction between a center and an outer circumferential part of the rear face plate.

3. The apparatus for plating according to claim 2, further comprising:
a first anode retainer configured to hold an outer circumferential part of the first face of the anode; and
a plurality of circumferential direction spacers provided between the rear face plate and the first anode retainer and arranged along the circumferential direction of the anode.

4. The apparatus for plating according to claim 3,
wherein the radial direction spacers are provided alternately in the plurality of circumferential direction spacers.

5. The apparatus for plating according to claim 4, further comprising:
a plurality of second anode retainers configured such that the circumferential direction spacers and the rear face plate are placed and fixed between the first anode retainer and second anode retainers, wherein the second anode retainers are provided corresponding to the circumferential direction spacers.

6. The apparatus for plating according to claim 1, further comprising:
a plurality of pin-type spacers provided to pass through the rear face plate and to come into contact with the anode.

7. The apparatus for plating according to claim 6,
wherein the pin-type spacer is screwed into a threaded hole of the rear face plate, such that a leading end of the pin-type spacer comes into contact with the anode.

8. An apparatus for plating, comprising:
a plating tank configured to store a plating solution therein;
an anode placed in the plating tank and provided with a plurality of through holes;
a substrate holder provided to hold a substrate to be opposed to the anode;
a barrier membrane placed to be brought into close contact with a first face on a substrate side of the anode; and
a bubble buffer ring provided to surround the anode and configured to have an end face that is placed at a position of a predetermined height in a direction farther from a second face of the anode, which is on an opposite side to the first face, and that regulates an amount of bubbles generated from the anode and accumulated on the second face.

9. The apparatus for plating according to claim 8, further comprising:
an anode retainer configured to hold an outer circumferential part of the first face of the anode, wherein
a predetermined clearance is formed between the bubble buffer ring and the anode retainer on an outer side of the anode.

10. The apparatus for plating according to claim 9,
wherein the bubble buffer ring includes a plurality of first portions having a first thickness and a plurality of second portions thicker than the first thickness, wherein the first portions and the second portions are arranged alternately in a circumferential direction of the bubble buffer ring, and
in a state that the second portions are brought into contact with the anode retainer, end faces of the first portions on a side farther from the substrate form the end face that regulates the amount of the bubbles, and the predetermined clearance is formed between the anode retainer and end faces of the first portions on a side nearer to the substrate.

11. The apparatus for plating according to claim 10, further comprising:
a second retainer member configured such that the second portions of the bubble buffer ring are placed and fixed between the anode retainer and the second retainer member.

12. The apparatus for plating according to any one of claims 1 to 11,
the apparatus for plating being configured such that a pressure of the plating solution in a cathode chamber that is on a substrate side of the barrier membrane becomes higher than a pressure of the plating solution in an anode chamber that is on an anode side of the barrier membrane, wherein
the barrier membrane is pressed against a substrate side-face of the anode by the pressure of the plating solution in the cathode chamber.

13. The apparatus for plating according to any one of claims 1 to 12,
wherein the plating tank is provided with a discharge outlet that is formed to communicate with the anode chamber and that is configured to discharge bubbles from the anode chamber to outside of the plating tank.

14. The apparatus for plating according to claim 13,
wherein a side wall of the plating tank has a height set, such that an overflow surface of the plating solution in the cathode chamber is higher than an overflow surface of the plating solution in the discharge outlet.

15. The apparatus for plating according to any one of claims 1 to 14,
wherein the barrier membrane is arranged to be pressed against a substrate side-face of the anode by a retainer plate having a plurality of through holes.

16. The apparatus for plating according to claim 15,
wherein a seal is provided in an outer circumferential part of the barrier membrane to seal between the retainer plate and the barrier membrane.

17. The apparatus for plating according to any one of claims 1 to 16,
wherein the barrier membrane is joined with a substrate side-face of the anode.

18. The apparatus for plating according to claim 17,
wherein the barrier membrane is joined with the substrate side-face of the anode via a joint layer having ion permeability.

19. The apparatus for plating according to either claim 17 or claim 18, further comprising:
a retainer ring configured to hold an outer circumferential part of the barrier membrane; and
a seal configured to seal between the retainer ring and the barrier membrane.

20. The apparatus for plating according to any one of claims 1 to 19,
wherein the anode is an insoluble anode.

21. The apparatus for plating according to any one of claims 1 to 20,
wherein the substrate holder holds the substrate in such a state that a plating surface or a surface to be plated of the substrate faces down, and
the anode is placed below the substrate and is opposed to the substrate.

22. A method of plating a substrate, the method comprising:
providing the apparatus for plating according to any one of claims 1 to 21; and
plating the substrate by using the apparatus for plating.
